(19) United States
(12) Patent Application Publication
(10) Pub. No.: US 2005/0208768 A1
(43) Pub. Date: Sep. 22, 2005

(54) Method for manufacturing gratings in semiconductor materials that readily oxidise

(76) Inventors: Richard Finlay, Toronto (CA); D. Gordon Knight, London (CA); Darren P. Goodchild, Gatineau (CA); Karin Hinzer, Ottawa (CA)

Correspondence Address: LACKENBACH SIEGEL, LLP, LACKENBACH SIEGEL BUILDING, 1 CHASE ROAD, SCARSDALE, NY, 10583, US

(21) Appl. No.: 10/978,632

(22) Filed: Nov. 1, 2004

Related U.S. Application Data
(60) Provisional application No. 60/516,408, filed on Oct. 31, 2003.

(51) Int. Cl. H01L 21/302; B44C 1/22

(52) U.S. Cl. 438/689; 216/41; 216/67; 216/83

(57) ABSTRACT

The present invention is a combination of in-situ etching with a grating mask pattern comprised only of semiconductor material, together with the fabrication of a protective layer beneath the semiconductor grating mask that protects the semiconductor material that readily oxidises. As such the present invention is based on a two-stage process. First the grating pattern is defined in a semiconductor material, wherein this pattern is called the semiconductor grating mask. The semiconductor grating mask sits on top of a layer of protective material, which in turn is on top of the semiconductor material that readily oxidises, wherein the protective layer prevents oxidation of the material below. The semiconductor structure is then moved to a reactor, where, in the second stage, the mask pattern is transferred into the underlying protective layer and the semiconductor material that readily oxidises, by in-situ etching. The grating is then overgrown in the same reactor without exposing the etched grating to the atmosphere. The overgrown material protects the underlying semiconductor material from oxidation when the structure is removed from the reactor.

### FIELD OF INVENTION

This application incorporates by reference and claims priority from Provisional Patent Application, Ser. No. 60/516,408, Filed Oct. 31, 2003.

The present invention pertains to the field of semiconductor lasers, and in particular to the method of manufacturing gratings in semiconductor materials that readily oxidise.

### BACKGROUND

Lasers that operate at high temperatures are in demand for many applications in telecommunications since packaging and operating costs are lower for lasers that can operate at high temperatures. Distributed feedback (DFB) lasers which contain Al(In,Ga)As in the active region have shown promise for high-temperature applications due to their relatively stable threshold current and efficiency over a wide temperature range. This behavior is described in publications such as T. J. Houle, et al, “A detailed comparison of temperature sensitivity of threshold for InGaAsP/InP, AlGaAs/GaAs, and AlInGaAs/InP lasers,” CLEO, CTuO1, Baltimore, Md., 2001; J. Piprek, et al, “What limits the maximum output power of long-wavelength AlGaInAs/InP laser diodes?” IEEE J. Quantum Electron. 38, 1253 (2002); and J. C. L. Yong, et al, “1.3-mm quantum-well InGaAsP, AlGaInAs, and InGaAsN laser material gain: A theoretical study,” IEEE J. Quantum Electron. 38, 1553 (2002).

Many semiconductor lasers, including DFB lasers and distributed Bragg reflector (DBR) lasers, contain a grating. This grating provides periodic reflections, either through all or a portion of the laser cavity or external to the laser cavity. The properties of the grating influence many properties of the laser including the efficiency, threshold current, operating wavelength and resistance to external perturbations. It is not unusual for DFB lasers in telecommunications applications to have gratings with periods as low as 200 nm, with feature sizes less than 100 nm.

There are two types of DFB lasers, namely index-coupled and gain-coupled. In index-coupled lasers, the grating is adjacent to the active region which is the material that emits the light. Because the grating doesn't enter the active region, the active region is not physically modified by the index-coupled grating, and therefore no etching or overgrowth is performed within the active region. One of the disadvantages of index-coupled DFB lasers is that their performance is heavily influenced by the position of the front and the rear facets with respect to the grating. In manufacturing, it is not possible to control this phenomenon, facet phase, in order to maximize yields. Furthermore, even when favorable facet phase is achieved, whether by accident or design, index-coupled lasers are sensitive to perturbation from reflections from other components in their packaging. Compared to DFB lasers with gain-coupled gratings, they can also have relatively slow response times. Despite these disadvantages, in research, manufacturing, and deployment in the telecommunications industry, most emphasis to date has been on index-coupled DFB lasers due to their ease of fabrication.

In gain-coupled DFB lasers the grating extends into the active region of the device. The grating's periodic interruption of the active region favors one mode of operation, the right-Bragg mode, and reduces sensitivity to the position of the facets with respect to the grating. This reduced sensitivity to facet phase improves the manufacturing yield of the laser. Furthermore, the gain-coupling makes the laser more resistant to external perturbation than an index-coupled laser, making it cheaper to package the laser with other optical components.

One of the least expensive ways to put a signal on a laser beam is to turn the source laser on and off at high speeds. This direct modulation is often cheaper than paying for a laser and a separate external modulator. In DFB lasers, the maximum effective modulation frequency is related to the relaxation oscillation frequency of the laser, which is the frequency at which the average small-signal modulation output power is maximized. Increasing the relaxation oscillation frequency increases the speed at which the laser can be directly modulated. Gain-coupled gratings increase the relaxation oscillation frequency by increasing the differential gain of the active region. This is another reason that there is an increasing demand for DFB lasers with gain-coupled gratings.

Distributed-feedback lasers with gain-coupled gratings are manufactured by growing semiconductor materials that comprise the active region onto a substrate wafer using an epitaxial technique such as metal-organic chemical-vapor deposition (MOCVD), molecular-beam epitaxy (MBE), chemical-beam epitaxy (CBE), or liquid-phase epitaxy (LPE). The grating is etched into the active region, and then the wafer is returned to the epitaxial reactor to cover the grating with additional semiconductor material. In conventional manufacturing techniques, the active region is exposed to the atmosphere before the overgrowth stage and the active region is exposed where the gain-coupled grating penetrates into the active region.

It is relatively straightforward to make the grating in an index-coupled laser with an active region containing semiconductor material that readily oxidises using known methods in the art. Conventional manufacturing techniques can be applied because the index-coupled grating doesn't extend into the active region and the etching of the grating can be terminated prior to reaching the active region, thereby not exposing the active region to the atmosphere. However, as described above, gain-coupled gratings are desired to reduce sensitivity to facet phase in the manufacturing process, increase resistance to external perturbations, and increase relaxation oscillation frequency by increasing differential gain. Therefore making gain-coupled gratings in active regions containing materials that readily oxidise, for example aluminum, is a challenge.

For example, materials from the Al(In,Ga)As material system, such as AlInAs, AlInGaAs, AlGaAs, and AlAs, oxidise readily when exposed to air. The oxide is very difficult to remove, and even if it could be removed, there would be a loss of resolution of the small features in the grating. This is a particular problem when making a gain-coupled distributed feedback laser where aluminum-containing materials are used in the active region. A grating that is etched in the conventional manner will oxidise before it can be installed in the MOCVD reactor for growth of the topside epitaxial layers. This oxide results in poor electrical, thermal, and physical properties of the material at the grating interface and as such results in a severe impact on chip performance and reliability.

Research groups in Asia and Europe have etched gratings into aluminum-containing materials, exposed the grating to ambient atmosphere, and then attempted to clean off or passivate the resulting oxide prior to the next epitaxial growth. For example, Chen et al., in their publication “A novel 1.3 μm high T₀ AlGaInAs/InP strained-compensated multi-quantum well complex-coupled distributed feedback laser diode,” Jpn. J. Appl. Phys., 1999, describe their attempt to passivate a surface of AlInAs using an etch in sulphuric acid. They attribute unfavorable device results, including high threshold current and low slope efficiency to non-radiative recombination at the resulting, imperfect, grating regrowth interface. Another research group, Kunzel et al., in their publication “MBE regrowth on AlGaInAs DFB gratings using in-situ hydrogen radical cleaning,” J. Crystal Gr, 1997, used reactive hydrogen radicals in an MBE system to clean a growth interface prior to growth. They demonstrate that the resulting material exhibits a PL intensity nearly 10-times lower than a structure grown without a regrowth interface, which is an indication of non-radiative recombination at the regrowth interface. Furthermore, their technique has not been demonstrated in an MOCVD reactor, the epitaxial technique that is overwhelmingly favored in the industry. Existing art has been of academic interest, since these results do not meet current standards for products in telecommunication applications; there is insufficient control of grating morphology in addition to little control of material quality at the growth interface.

An existing approach to reduce contamination at a growth interface, while achieving good etch control, is in-situ etching. In-situ etching is etching inside a reactor that is conventionally used for epitaxial growth, such as a reactor for MBE, CBE, or MOCVD. After etching, the same reactor can be used to grow a semiconductor material on top of the etched surface. For example, Knight in U.S. Pat. No. 5,869,398 has shown that InP may be etched in an MOCVD reactor and then additional InP may be grown on the etched surface without exposing the surface to atmosphere. This in-situ etch and overgrowth procedure reduced the levels of silicon and oxygen contamination at the growth interface compared to samples that did not receive in-situ etching prior to overgrowth. A limitation of this approach is that conventional methods of defining the pattern to be etched are not suitable. With conventional methods of defining the pattern to be etched, the sample must be removed from the reactor to remove the mask material. For example, if a pattern were defined in photoresist or dielectric (such as SiO₂ or SiNₓ), the wafer would have to be removed from the reactor to strip this masking material, exposing the etched surface to contamination.

Therefore there is a need for a suitable method for etching gratings into semiconductor material that readily oxidises.

This background information is provided for the purpose of making known information believed by the applicant to be of possible relevance to the present invention. No admission is necessarily intended, nor should be construed, that any of the preceding information constitutes prior art against the present invention.

### SUMMARY OF THE INVENTION

An object of the present invention is to provide a method for manufacturing gratings in semiconductor materials that readily oxidise. In accordance with an aspect of the present invention, there is provided a method for manufacturing a grating pattern in one or more layers of semiconductor material that readily oxidises, the method comprising the steps of: forming a protective layer on top of the one or more layers, the protective layer formed from a semiconductor material and providing protection to the one or more layers; forming a grating pattern in a semiconductor material grown on the protective layer, thereby forming a semiconductor grating mask; transferring the grating pattern into the one or more layers using in-situ etching in an epitaxial growth reactor; and overgrowing semiconductor material on the one or more layers prior to removal from the epitaxial growth reactor.

In accordance with another aspect of the present invention there is provided a semiconductor device comprising: one or more layers of semiconductor material that readily oxidises, said one or more layers having a grating pattern etched therein; a protective layer on the one or more layers, said protective layer having the grating pattern therein; an overgrowth layer of semiconductor material grown on the protective layer, said overgrowth layer encapsulating the grating pattern in the one or more layers.

### BRIEF DESCRIPTION OF THE FIGURES

FIG. 1 shows the semiconductor structure prior to etching the grating mask according to one embodiment of the present invention.

FIG. 2 shows the semiconductor structure after the formation of the grating mask according to one embodiment of the present invention.

FIG. 3 shows the semiconductor structure after the in-situ etch to create the grating in the active region according to one embodiment of the present invention.

FIG. 4 shows the semiconductor structure after overgrowth according to one embodiment of the present invention.

FIG. 5 shows the semiconductor structure with the grating pattern defined, according to one embodiment of the present invention.

FIG. 6 shows the semiconductor structure prior to the completion of the etching of the grating mask according to one embodiment of the present invention.

### DETAILED DESCRIPTION OF THE INVENTION

The present invention provides a method of manufacturing gratings in semiconductor material that readily oxidises. The method is suitable for a wide range of applications, and is particularly appropriate for fabricating gratings for distributed feedback lasers, gratings for distributed Bragg reflectors, and filters based on optical waveguides with grating structures, for example. The invention provides an improved accuracy of the grating depth and shape, and a reduction in contaminants and oxidants within the gratings etched into the semiconductor material that readily oxidises, with consequent improved performance and manufacturing repeatability thereof, for example.

The present invention is a combination of in-situ etching with a grating mask pattern comprised only of semiconductor material, together with the fabrication of a protective layer beneath the semiconductor grating mask that protects the semiconductor material that readily oxidises. As such the present invention is based on a two-stage process. First the grating pattern is defined in a semiconductor material, wherein this pattern is called the semiconductor grating mask. The semiconductor grating mask sits on top of a layer of protective material, which in turn is on top of the semiconductor material that readily oxidises, wherein the protective layer prevents oxidation of the material below. The semiconductor structure is then moved to a reactor, where, in the second stage, the mask pattern is transferred into the underlying protective layer and the semiconductor material that readily oxidises, by in-situ etching. The grating is then overgrown in the same reactor without exposing the etched grating to the atmosphere. The overgrown material protects the underlying semiconductor material from oxidation when the structure is removed from the reactor.

The protective layer between the semiconductor grating mask and the semiconductor material that readily oxidises, protects this material from oxidation until the protective layer is pierced during the in-situ etching process. The semiconductor grating mask and the protective layer are partially etched, or entirely etched away, during in-situ etching, wherein the material that remains is incorporated into the finished structure during the overgrowth stage. This incorporation of the masking and protective material into the final structure means that the structure doesn't have to be removed from the reactor between etching and overgrowth in order to remove the masking material. When the semiconductor material that readily oxidises is exposed after the in-situ etching process, the structure is in an environment that precludes oxidation until the overgrown material seals in this semiconductor material in the subsequent step.

The combination of the semiconductor material grating mask together with in-situ etching and overgrowth additionally allows the formation of gratings on a semiconductor with minimal contamination. As such, there is no need to compensate for n-type doping from the contamination by addition of excessive p-type dopants and thereby increasing the optical absorption of the waveguide. This invention has the added benefit of providing exceptional grating depth uniformity over a full wafer, and process repeatability.

In addition the present invention can provide a means for overcoming the difficulties with creating a grating in the active region of a semiconductor laser wherein this active region comprises semiconductor material that readily oxidises.

The present invention is suitable for manufacturing a wide range of grating structures, provided a semiconductor material grating mask and a protective layer can be produced. Suitable grating structures include regularly-spaced corrugations, such as those found in a conventional DFB laser, variable-spaced corrugations, such as those found in devices containing a chirped grating, and more complicated groups of corrugations, such as those found in devices containing a distributed Bragg reflector.

The invention is appropriate for the manufacturing of a grating in a variety of semiconductor materials, but it is of greatest benefit for materials that oxidise readily when exposed to air, for example materials of a Al(In,Ga)As type compound such as AlInGaAs, AlGaAs, and AlInAs. The invention is suitable for making gain-coupled gratings into active regions comprised of multiple quantum-well/quantum-barrier stacks of various In(Ga,As)P and Al(In,Ga)As materials. While the present invention is described such that the semiconductor material that readily oxidises contains aluminum, the invention is suitable for any material that readily oxidises, wherein this material can provide a desired effect on the functionality of the semiconductor laser. In addition, embodiments of the present invention describe the use of this manufacturing method enabling the creation of gratings in the active region of a semiconductor laser, however other layers of the semiconductor laser may comprise semiconductor materials that readily oxidise and require a grating structure therein. As such these other layers can equally be manufactured using the method according to the present invention.

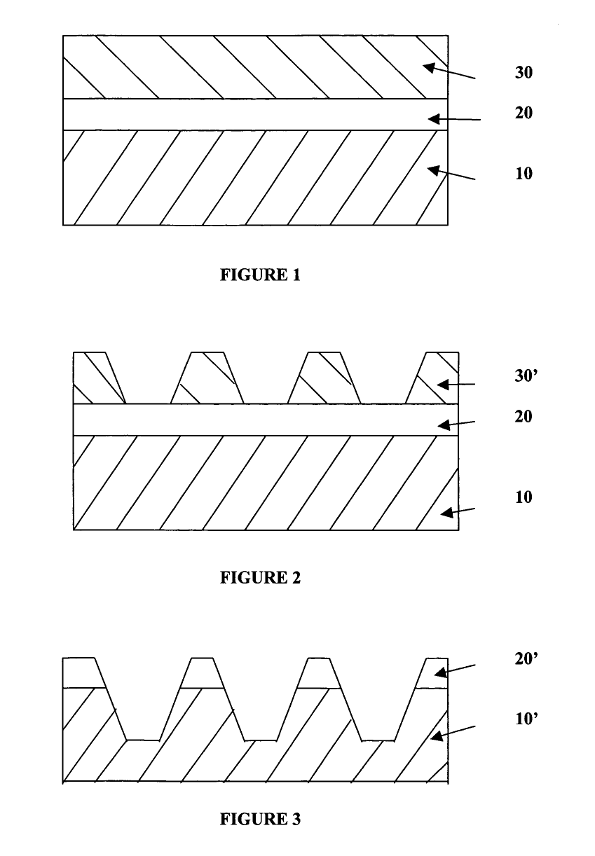

One embodiment of the current invention is depicted in FIG. 1. FIG. 1 shows a cross-sectional view of a semiconductor structure to have a grating defined in accordance with the present invention. Layer 10 is the material to receive the grating pattern, wherein layer 10 may comprise multiple layers of semiconductor material. A portion of the material in layer 10 is the material that is at risk of oxidation. There may be additional layers in the structure beneath layer 10, not represented in this diagram. Layer 20 may be comprised of multiple layers of semiconductor material, wherein layer 20 is the protective layer which will protect layer 10 from oxidation. Layer 20 comprises materials that resist oxidation when exposed to the atmosphere, and can be etched during the in-situ etch process. Layer 30 is the material that will become the semiconductor grating mask.

The structure represented in FIG. 1 is etched to produce the structure represented in FIG. 2. Layer 30 has been patterned to make a semiconductor grating mask, represented as layer 30′, wherein layer 20 protects the materials in layer 10 from oxidation.

The structure represented in FIG. 2 is placed into an epitaxial reactor where in-situ etching is used to transfer the pattern in the semiconductor grating mask through the protective layer 20, and into layer 10. Layer 10′ in FIG. 3 represents the original layer 10 with the grating pattern etched therein. Layer 20′ represents the patterned protective layer. In this embodiment of the invention, we assume that layer 30′ is completely etched away during the in-situ etch, and that layer 20′ is thinner than layer 20 because some of layer 20 is etched away during the in-situ etching. However, in an alternate embodiment, layer 30′ may not be fully etched away during the in-situ etching process and as such in this instance layer 30′ must be accounted for in the design and performance of the resulting semiconductor laser, as would be readily understood by a worker skilled in the art.

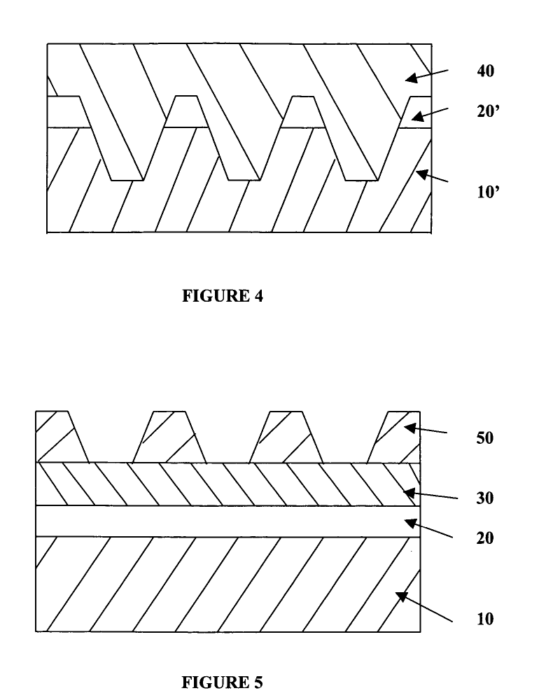

Without removing the wafer from the reactor, semiconductor material from the In(Ga,As)P or Al(In,Ga)As or other suitable semiconductor material system that is compatible with the substrate and other semiconductor layers, labeled as layer 40, is grown on top of the patterned layers 10′ and 20′ to yield the structure represented in FIG. 4. The finished grating is defined by the corrugation in layers 10′ and 20′. Additional layers, not represented in FIG. 4, may be grown on top of layer 40. When the structure is removed from the reactor the region with the grating is sealed inside the semiconductor, thereby protected from oxidation and contamination. Between the etching and the overgrowth stages there is no opportunity for oxidation or contamination to occur due to the controllable environment within the reactor, thereby yielding a reproducible manufacturing process with low levels of defects due to oxidation and/or contamination.

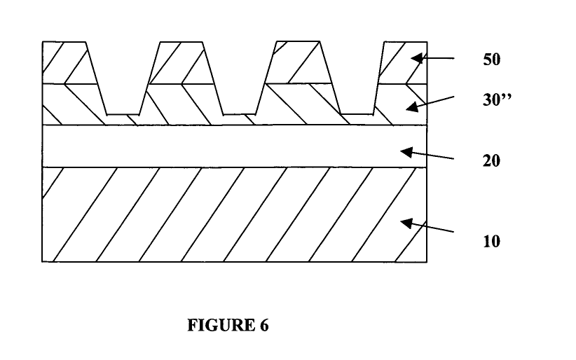

A further aspect of the invention is the means of forming the semiconductor grating mask, illustrated by layer 30′ in FIG. 2. An embodiment of the invention applied to convert layer 30 in FIG. 1 to layer 30′ in FIG. 2 is illustrated in FIGS. 5 and 6.

Conventional means are used to create a grating pattern in a masking material on top of layer 30, as represented by layer 50 in FIG. 5. The structure in FIG. 5 is then etched using an etch process that etches the material in layer 30, using the material in layer 50 as a mask. In the embodiment described in the accompanying figures, the etch is terminated near the bottom of layer 30, before penetrating layer 20, which represents the protective layer. FIG. 6 represents the structure after the etching process is complete. In the final stage of preparation of the semiconductor grating mask, a selective etch process is used to remove the remaining portions of layer 30″ from the bottom of the grating teeth. The selective etchant should etch the material of layer 30 but not etch the material of layer 20, in order to stop transferring the pattern before piercing layer 20, thereby ensuring layer 20 protects the semiconductor materials in layer 10 from oxidation. After the masking material (layer 50) is stripped, the resulting structure is that depicted in FIG. 2.

In one embodiment of the invention, layer 10 is the active region of a DFB laser. The active region comprises a quantum-well/quantum barrier stack including materials from the Al(In,Ga)As and In(Ga,As)P material systems. In this embodiment, layer 20 is a 5-nm thick layer of InP that protects the underlying active region from oxidation. In this embodiment, layer 30 is a 50-nm thick layer of InGaAs. It will be obvious to workers skilled in the art that other layer thicknesses and materials could be applied to the same conceptual process, and such other thicknesses and materials are within the scope of this invention. In this embodiment of the invention, the material grown in layer 40 is the same composition as the material in layer 20′, and as such layers 40 and 20′ are virtually indistinguishable.

In one embodiment of the invention, the etch that patterns layer 30 of FIG. 5 to make layer 30″ illustrated in FIG. 6 is an etch in an inductively-coupled plasma using HBr source gas. In this embodiment of the invention, the remaining InGaAs at the bottom of the grating teeth illustrated in FIG. 6 is etched using an aqueous solution of citric acid. This acid is selected because it etches InGaAs at a controllable rate, and it stops etching when it reaches the InP in layer 20 at the bottom of the grating teeth.

Other embodiments of the invention are possible wherein the etchant that patterns layer 30 self-terminates when it reaches layer 20. In such an embodiment there is no need to stop etching when the structure resembles that illustrated in FIG. 6. In such an embodiment, after the etch is complete and the masking material is removed, the structure resembles that illustrated in FIG. 2 without an additional selective wet etch step being performed. In one embodiment an inductively-coupled plasma is used to etch most of the way through layer 30, yielding the structure illustrated in FIG. 6. This method is advantageous because it yields more vertical grating sidewalls than can be achieved using a single etch step with a selective etchant.

In one embodiment of the invention, the masking material in layer 50 is a dielectric material, for example silicon oxide, silicon nitride or silicon oxynitride, wherein this dielectric may be patterned using methods known in the art. For example, it can be etched in a plasma etch process or a wet etch process using a photoresist mask. The photoresist can be patterned holographically, which is a technique well known in the art. Those skilled in the art will appreciate that any other suitable lithography process may be used to create the photoresist grating mask, including electron-beam lithography, near-field holography, and nano-imprint lithography. Those skilled in the art will recognize that the grating pattern defined in layer 50 may be a uniform corrugation, or it may include phase jumps, chirped periods, or patches of gratings, and that in cases where the grating pattern is irregular, electron-beam lithography would be a favorable means of patterning the photoresist.

In one embodiment of the invention the in-situ etching and overgrowth is conducted in an MOCVD reactor. It will be obvious to a worker skilled in the art that application of other epitaxial growth technologies is possible, including chemical-beam epitaxy (CBE), molecular-beam epitaxy (MBE) and liquid-phase epitaxy (LPE). A key part of this process is the control of the physical depth of the transfer of the pattern into layer 10, wherein the etch rate is dependent on the materials being etched, the etchant, the etchant flux and the temperature. In one embodiment of the invention, the transfer of the grating pattern from layer 30′ to layer 10 is accomplished with in-situ etching using HCl. It would be obvious to a worker skilled in the art that other halogen-containing compounds would be suitable etchants, including, but not limited to methyl chloride, tertiarybutyl chloride, hydrogen iodide, diiodomethane, triiodomethane, carbon tetraiodide, iodoethane, n-propyl iodide and isopropyl iodide. However, HCl is used in this embodiment because it etches Al(In,Ga)As compounds, and it etches the InP protective layer, while it does not etch InGaAs too quickly. As would be readily understood, the control of the temperature and other parameters is critical to the accuracy of the depth of the grating that is etched into the active layer comprising semiconductor material that readily oxidises.

After the processing steps described in this invention are complete the semiconductor structure will be processed by conventional means to complete the device fabrication.

As illustrated in the Figures, the sizes of layers or regions are exaggerated for illustrative purposes and, thus, are provided to illustrate the general structures of the present invention. Various aspects of the present invention are described with reference to a layer or structure being formed on a substrate or other layer or structure. As will be appreciated by those of skill in the art, references to a layer being formed “on” another layer or substrate contemplates that additional layers may intervene.

In addition it would be readily understood by a worker skilled in the art that while the Figures illustrate a particular number of layers, each of these identified layers can be formed by a plurality of layers depending on the targeted application.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A method for manufacturing a grating pattern in one or more layers of semiconductor material that readily oxidises, the method comprising the steps of:
(a) forming a protective layer on top of the one or more layers, the protective layer formed from a semiconductor material and providing protection to the one or more layers;
(b) forming a grating pattern in a semiconductor material grown on the protective layer, thereby forming a semiconductor grating mask;
(c) transferring the grating pattern into the one or more layers using in-situ etching in an epitaxial growth reactor; and
(d) overgrowing semiconductor material on the one or more layers prior to removal from the epitaxial growth reactor.

2. The method for manufacturing a grating pattern in one or more layers of semiconductor material that readily oxidises according to claim 1, wherein the step of forming a grating pattern comprises the steps of:
(a) creating a desired grating pattern in a masking material deposited on the semiconductor material grown on the protective layer, thereby defining a mask;
(b) partially etching said semiconductor material grown on the protective layer as defined by the mask;
(c) selectively etching said semiconductor material grown above the protective layer to form the grating pattern, thereby forming the semiconductor grating mask; and
(d) stripping said masking material.

3. The method for manufacturing a grating pattern in one or more layers of semiconductor material that readily oxidises according to claim 2, wherein the step of selectively etching is performed using an inductively-coupled plasma.

4. The method for manufacturing a grating pattern in one or more layers of semiconductor material that readily oxidises according to claim 2, wherein the step of selectively etching terminates upon reaching the protective layer based on a selected etchant.

5. The method for manufacturing a grating pattern in one or more layers of semiconductor material that readily oxidises according to claim 2, wherein the step of creating a desired grating pattern is performed using a plasma etch process or a wet etch process using a photoresist mask.

6. The method for manufacturing a grating pattern in one or more layers of semiconductor material that readily oxidises according to claim 2, wherein the masking material is a dielectric material.

7. The method for manufacturing a grating pattern in one or more layers of semiconductor material that readily oxidises according to claim 1, wherein during the step of transferring the grating pattern, the semiconductor material grown on the protective layer is partially etched away.

8. The method for manufacturing a grating pattern in one or more layers of semiconductor material that readily oxidises according to claim 1, wherein during the step of transferring the grating pattern, the semiconductor material grown on the protective layer is completely etched away.

9. The method for manufacturing a grating pattern in one or more layers of semiconductor material that readily oxidises according to claim 1, wherein the epitaxial growth reactor is a MOCVD reactor.

10. The method for manufacturing a grating pattern in one or more layers of semiconductor material that readily oxidises according to claim 1, wherein the one or more layers of semiconductor material are selected from an Al(In,Ga)As material system.

11. The method for manufacturing a grating pattern in one or more layers of semiconductor material that readily oxidises according to claim 1, wherein the protective layer is InP.

12. The method for manufacturing a grating pattern in one or more layers of semiconductor material that readily oxidises according to claim 1, wherein the semiconductor material grown on the protective layer is InGaAs.

13. The method for manufacturing a grating pattern in one or more layers of semiconductor material that readily oxidises according to claim 12, wherein the step of selectively etching is performed using an inductively-coupled plasma using HBr.

14. The method for manufacturing a grating pattern in one or more layers of semiconductor material that readily oxidises according to claim 13, wherein the step of selectively etching further includes etching using an aqueous solution of citric acid.

15. The method for manufacturing a grating pattern in one or more layers of semiconductor material that readily oxidises according to claim 1, wherein material deposited during the step of overgrowing and material forming the protective layer have identical compositions.

16. The method for manufacturing a grating pattern in one or more layers of semiconductor material that readily oxidises according to claim 1, wherein the one or more layers of semiconductor material form an active region of a DFB laser.

17. A semiconductor device comprising:
(a) one or more layers of semiconductor material that readily oxidises, said one or more layers having a grating pattern etched therein;
(b) a protective layer on the one or more layers, said protective layer having the grating pattern therein;
(c) an overgrowth layer of semiconductor material grown on the protective layer, said overgrowth layer encapsulating the grating pattern in the one or more layers.

18. The semiconductor device according to claim 17, said semiconductor device having an active region and said active region is located within the one or more layers.

19. The semiconductor device according to claim, 17, wherein the one or more layers are selected from an Al(In,Ga)As material system.

20. The semiconductor device according to claim 17, wherein the protective layer is InP.

21. The semiconductor device according to claim 17, wherein the overgrowth layer is InGaAs.

22. The semiconductor device according to claim 17, wherein the protective layer and the overgrowth layer have identical material compositions.
